(19) United States
(12) Patent Application Publication
(10) Pub. No.: US 2013/0255760 A1
(43) Pub. Date: Oct. 3, 2013

(54) SOLAR CELL AND METHOD OF MANUFACTURING THE SAME

(71) Applicant: Dong-Jin KIM, Yongin-si (KR)

(72) Inventor: Dong-Jin KIM, Yongin-si (KR)

(21) Appl. No.: 13/572,784

(22) Filed: Aug. 13, 2012

(30) Foreign Application Priority Data
Mar. 28, 2012 (KR) 10-2012-0031816

(51) Int. Cl. H01L 31/0224; H01L 31/18

(52) U.S. Cl. 136/256; 438/98; 257/E31.126

(57) ABSTRACT

A solar cell includes a substrate, a rear electrode layer on the substrate, the rear electrode layer is divided by a first pattern unit, a light absorption layer on the rear electrode layer, the light absorption layer is divided by a second pattern unit that is spaced apart from the first pattern unit, a translucent electrode layer on the light absorption layer, the translucent electrode layer is divided by a third pattern unit that is spaced apart from the first and second pattern units, and a light transmission unit that extends through the rear electrode layer and the light absorption layer. The light transmission unit is between the second pattern unit and the third pattern unit.

### CROSS-REFERENCE TO RELATED APPLICATION

This application claims priority to Korean Patent Application No. 10-2012-0031816, filed on Mar. 28, 2012, in the Korean Intellectual Property Office, and entitled: “Solar Cell and Method of Manufacturing the Same,” is incorporated by reference herein in its entirety.

### BACKGROUND

As existing energy resources, such as oil and coal, are expected to be exhausted, interest in alternative energies for replacing the existing energy resources has risen. From among the alternative energies, solar cells have been drawing attention as next generation batteries that are used to directly change solar energy into electric energy by using semiconductor devices.

### SUMMARY

Embodiments may be realized by providing a solar cell including a substrate, a rear electrode layer on the substrate, the rear electrode layer is divided by a first pattern unit, a light absorption layer on the rear electrode layer, the light absorption layer is divided by a second pattern unit, the second pattern unit is spaced apart from the first pattern unit, a translucent electrode layer on the light absorption layer, the translucent electrode layer is divided by a third pattern unit, the third pattern unit is spaced apart from the first and second pattern units, a light transmission unit extending through the rear electrode layer and the light absorption layer, and the light transmission unit is between the second pattern unit and the third pattern unit.

The translucent electrode layer may fill the second pattern unit and the light transmission unit. The third pattern unit may expose a top surface of the rear electrode layer and the third pattern unit may include therein an insulating unit that is on the rear electrode layer. The light transmission unit may overlap the second pattern unit. The solar cell may include a buffer layer between the light absorption layer and the translucent electrode layer.

The rear electrode layer may include Mo. The light absorption layer may include Cu, In, Ge, and Se.

The third pattern unit may contact the light transmission unit. The light transmission unit may be directly between the second pattern unit and the third pattern unit such that the light transmission unit contacts the third pattern unit and the second pattern unit.

The first pattern unit and the light transmission unit may expose different regions of a top surface of the substrate. The first pattern unit may be spaced apart from the light transmission unit by the second pattern unit. The second pattern unit and the third pattern unit may expose different regions of a top surface of the rear electrode layer. The third pattern unit may be spaced apart from the first pattern unit by the light transmission unit and the second pattern unit. The light absorption layer may fill the first pattern unit and the translucent electrode layer may fill the second pattern unit and the light transmission unit. An insulating material may fill the third pattern unit.

The light transmission unit may abut the second pattern unit and the third pattern unit. The insulating material in the third pattern unit may be in contact with a portion of the translucent electrode layer that fills both the second pattern unit and the light transmission unit.

Embodiments may also be realized by providing a method of manufacturing a solar cell that includes forming a rear electrode layer on a substrate and performing a first patterning process to form a first pattern unit that divides the rear electrode layer, forming a light absorption layer on the rear electrode layer and performing a second patterning process to form a second pattern unit that divides the light absorption layer, the second pattern unit is formed at a location spaced apart from the first pattern unit, exposing a portion of a top surface of the substrate by removing parts of the light absorption layer and the rear electrode layer to form a light transmission unit, forming a translucent electrode layer on the light absorption layer and on the portion of the top surface of the substrate that is exposed by the light transmission unit, and performing a third patterning process to form a third pattern unit at a location spaced apart from the first and second pattern units.

The parts of the light absorption layer and the rear electrode layer that are removed to expose the portion of the top surface of the substrate may be between the second pattern unit and the third pattern unit. The parts of the light absorption layer and the rear electrode layer may be removed by radiating a laser.

The method may include forming a buffer layer on the light absorption layer before forming the second pattern unit. The third patterning process may be performed via a mechanical scribing method. The parts of the light absorption layer and the rear electrode layer that are removed to form the light transmission unit may abut the second pattern unit. The third pattern unit may be formed to contact an area where the light absorption layer and the rear electrode layer are removed.

Forming the first pattern unit and the light transmission unit may include exposing different regions of the top surface of the substrate such that the first pattern unit is spaced apart from the light transmission unit by the second pattern unit. Forming the second pattern unit and the third pattern unit may include exposing different regions of a top surface of the rear electrode layer such that the third pattern unit is spaced apart from the first pattern unit by the light transmission unit and the second pattern unit. Forming the light absorption layer may include filling the first pattern unit. Forming the translucent electrode layer may include filling the second pattern unit and the light transmission unit. The third pattern unit may be filled with an insulating material.

The light transmission unit may be formed to abut the second pattern unit and the third pattern unit such that the insulating material in the third pattern unit is in contact with a portion of the translucent electrode layer that fills both the second pattern unit and the light transmission unit.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a building integrated photovoltaic (BIPV) type solar cell;

FIG. 2 illustrates a plan view of a solar cell according to an exemplary embodiment;

FIG. 3 illustrates a cross-sectional view taken along a line I-I′ of FIG. 2;

FIG. 4 illustrates a cross-sectional view of a solar cell according to an exemplary embodiment; and

FIGS. 5 to 8 illustrate cross-sectional views depicting stages in a method of manufacturing a solar cell according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art. Accordingly, the embodiments are merely described below, by referring to the figures, to explain aspects of the present description.

In the figures, the dimensions of layers and regions may be exaggerated for clarity of illustration. Like reference numerals refer to like elements throughout. It will also be understood that when a layer or element is referred to as being “on” another layer or substrate, it can be directly on the other layer or substrate, or intervening layers may also be present. Further, it will also be understood that when a layer is referred to as being “between” two layers, it can be the only layer between the two layers, or one or more intervening layers may also be present. As used herein, the term “and/or” includes any and all combinations of one or more of the associated listed items.

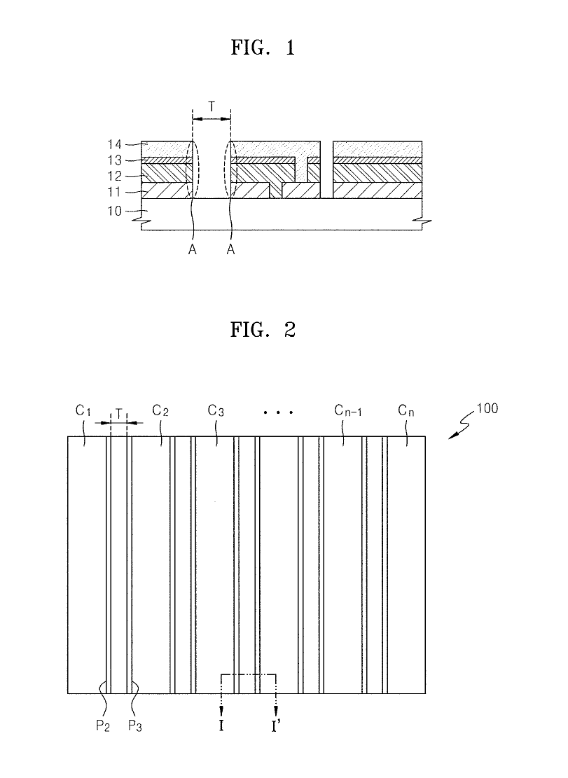

FIG. 1 illustrates a cross-sectional view of a solar cell used in a building integrated photovoltaic (BIPV) system. A rear electrode layer 11, a light absorption layer 12, a buffer layer 13, and a translucent electrode layer 14 may be sequentially stacked on a substrate 10 to form a stacked structure. A light transmission unit T may be formed in the stacked structure, e.g., the light transmission unit T may expose a portion of the substrate 10. The light transmission unit T may be formed through a laser scribing process. Thereafter, a method of forming the solar cell may include patterning a conductive material (e.g., a transparent conducting oxide (TCO)-based translucent electrode layer), which conductive material may later be redeposited on a side surface of the light transmission unit T, on a portion ‘A’ of FIG. 1. This may result in the formation of a shunt resistance path, i.e., an unnecessary current path, and thus generation efficiency of the solar cell may deteriorate.

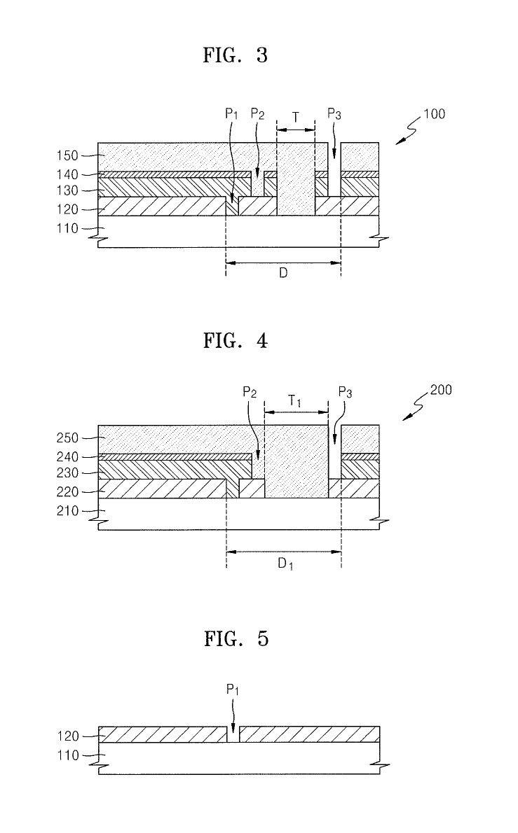

In contrast, FIG. 2 illustrates a plan view of a solar cell 100 according to an exemplary embodiment; and FIG. 3 illustrates a cross-sectional view taken along a line I-I′ of FIG. 2.

Referring to FIGS. 2 and 3, according to an exemplary embodiment, the solar cell 100 may include a substrate 110 and a rear electrode layer 120 disposed on the substrate 110. The rear electrode layer 120 may be divided by a first pattern unit P1, e.g., the rear electrode layer 120 may include a plurality of rear electrode layers 120 that are spaced apart by the first pattern unit P1. A light absorption layer 130 may be disposed on the rear electrode layer 120 and divided by a second pattern unit P2, e.g., the light absorption layer 130 may include a plurality of light absorption layers 130 that are spaced apart by the second pattern unit P2. The second pattern unit P2 may be spaced apart from the first pattern unit P1 so as to be in a non-overhanging relationship.

The light absorption layer 130, and a buffer layer 140 and a translucent electrode layer 150 stacked on the light absorption layer 130, may be further divided by a third pattern unit P3. The third pattern unit P3 may be spaced apart from the second pattern unit P2. A light transmission unit T may be formed by removing other portions of at least the rear electrode layer 120 and the light absorption layer 130. According to an exemplary embodiment, the light transmission unit T may be spaced apart from each of the first pattern unit P1, the second pattern unit P2, and the third pattern unit P3.

The substrate 110 may be, e.g., a glass substrate having excellent light translucency, or a polymer substrate. The glass substrate may be formed of a material such as sodalime glass or high strained point soda glass, and the polymer substrate may be formed of a material such as a polyimide. However, the materials and construction of the substrate 110 are not limited thereto, e.g., the glass substrate may be formed of low iron tempered glass protecting internal devices from external shocks and containing a low amount of iron to increase transmittance of sunlight. For example, in the low iron sodalime glass, sodium (Na) ions in the glass may be eluted at a process temperature higher than 500° C., and thus efficiency of the light absorption layer 130 formed of Copper-Indium-Gallium-Selenide (CIGS) may be improved.

The rear electrode layer 120 may be formed of a metal having excellent conductivity and excellent light reflectivity, such as molybdenum (Mo), aluminum (Al), and/or copper (Cu). Charges formed by a photoelectric effect may be collected, and may be re-absorbed by the light absorption layer 130 by the rear electrode layer 120 reflecting light penetrating through the light absorption layer 130. For example, the rear electrode layer 120 may include Mo in consideration of high conductivity, an ohmic-contact with the light absorption layer 130, and high temperature stability in a selenium (Se) atmosphere.

The rear electrode layer 120 may have a thickness from about 200 nm to about 500 nm, and may be divided into multiple parts by the first pattern unit P1. The first pattern unit P1 may be a groove parallel to one direction of the substrate 110 so that the groove exposes the substrate 110.

The rear electrode layer 120 may be doped with alkali ions, such as Na. For example, while growing the light absorption layer 130 formed of CIGS, the alkali ions doped on the rear electrode layer 120 are mixed with the light absorption layer 130. Accordingly, there may be a structurally favorable effect on the light absorption layer 130 and conductivity of the light absorption layer 130 may be improved. A stand-off ratio Voc of the solar cell 100 may also be increased.

According to an exemplary embodiment, the rear electrode layer 120 may be formed of multiple films so as to obtain resistance characteristics of a contact surface with the substrate 110 and the rear electrode layer 120.

The light absorption layer 130 may be formed of a CIGS-based compound to form a P-type semiconductor layer, and absorb incident sunlight.

The light absorption layer 130 may have a thickness from about 0.7 μm to about 2 μm. The light absorption layer 130 may be formed in the first pattern unit P1 so as to separate parts of the rear electrode layer 120, e.g., the light absorption layer 130 may completely fill the first pattern unit P1.

The light absorption layer 130 may be divided into multiple parts by the second pattern unit P2. The second pattern unit P2 may be a groove extending in a direction parallel to the first pattern unit P1 and at a different location from the first pattern unit P1. A top surface of the rear electrode layer 120 may be exposed by the second pattern unit P2.

The translucent electrode layer 150 may be formed on the light absorption layer 130 to form a P-N junction with the light absorption layer 130. The translucent electrode layer 150 may be formed of a transparent conductive material, such as boron doped zinc oxide (ZnO:B), indium tin oxide (ITO), or indium zinc oxide (IZO), so as to capture charges formed by a photoelectric effect. Although not shown in FIG. 2, the top surface of the translucent electrode layer 150 may be textured so as to reduce reflection of incident sunlight and increase light absorption in the light absorption layer 130.

The translucent electrode layer 150 may be formed inside the second pattern unit P2, e.g., the translucent electrode layer 150 may completely fill the second pattern unit P2. Parts of the translucent electrode layer 150 within the second pattern unit P2 may be in contact, e.g., direct contact, with the rear electrode layer 120 exposed by the second pattern unit P2. Accordingly, the light absorption layer 130, which is divided into multiple parts by the second pattern unit P2, may be electrically connected.

The translucent electrode layer 150 may be divided into multiple parts by the third pattern unit P3 formed at a different location from the first and second pattern units P1 and P2. The third pattern unit P3 may be a groove extending in a direction parallel to the first and second pattern units P1 and P2. The third pattern unit P3 may extend to expose the top surface of the rear electrode layer 120, thereby forming a plurality of first through nth photoelectric conversion cells Cl to Cn on the substrate 110.

An insulation material, such as air, may be disposed in the third pattern unit P3 so as to form an insulation layer between the first through nth photoelectric conversion cells Cl to Cn. The first through nth photoelectric conversion cells Cl to Cn may be connected in series.

The buffer layer 140 may be formed between the light absorption layer 130 and the translucent electrode layer 150, e.g., thereby reducing a band gap between the light absorption layer 130 and the translucent electrode layer 150 and decreasing recombination between electrons and holes that may be generated in an interface between the light absorption layer 130 and the translucent electrode layer 150. The buffer layer 140 may be formed of, e.g., CdS, ZnS, In₂S₃, ZnₓMg₍₁₋ₓ₎O, or the like.

Referring to FIGS. 2 and 3, the light transmission unit T may be formed extending in a direction parallel to the first to third pattern units P1 to P3 in a portion where parts of the rear electrode layer 120, the light absorption layer 130, and the buffer layer 140 are removed. The translucent electrode layer 150 may be filled in the portion where parts of the rear electrode layer 120, the light absorption layer 130, and the buffer layer 140 are removed. The translucent electrode layer 150 may completely fill the light transmission unit T.

In other words, according to an exemplary embodiment, the light transmission unit T is formed in a non-generation area D between the second pattern unit P2 and the third pattern unit P3. Accordingly, even if a laser scribing process for forming the light transmission unit T is performed, the solar cell 100 may not be affected by a shunt formed due to a conductive material being redeposited on a side surface of the light transmission unit T, thereby reducing the possibility of and/or preventing deterioration of efficiency of the solar cell 100 by the shunt.

The translucent electrode layer 150 may be filled in the light transmission unit T, which may be formed by removing the parts of each of the rear electrode layer 120, the light absorption layer 130, and the buffer layer 140. Accordingly, the first to nth photoelectric conversion cells Cl to Cn divided by the third pattern unit P3 may be connected to one another in series, and even if a conductive material is redeposited on a side surface of the light transmission unit T, a shunt never affects the solar cell 100.

Since the light transmission unit T is formed of the translucent electrode layer 150 and the substrate 110 is formed of, e.g., glass having an excellent light translucency, a sufficient light translucency may be obtained. Accordingly, the solar cell 100 may be used for a BIPV system.

FIG. 4 illustrates a cross-sectional view of a solar cell 200 according to another exemplary embodiment.

Referring to FIG. 4, a solar cell 200 may include a substrate 210, a rear electrode layer 220, a light absorption layer 230, a buffer layer 240, a translucent electrode layer 250, and a light transmission unit T1.

The substrate 210, the rear electrode layer 220, the light absorption layer 230, the buffer layer 240, and the translucent electrode layer 250 are substantially the same as the substrate 110, the rear electrode layer 120, the light absorption layer 130, the buffer layer 140, and the translucent electrode layer 150, respectively, that are described with reference to FIGS. 2 and 3, respectively, and thus a detailed description of like features will be omitted.

Referring to FIG. 4, a light transmission unit T1 may be formed to overlap with the entire or a part of a second pattern unit P2. In other words, the second pattern unit P2 and the light transmission unit T1, may both be filled by the translucent electrode layer 250, so as to be contiguously formed as one continuous opening. Accordingly, the light transmission unit T1 may abut, e.g., be in a flush arrangement with, the second pattern unit P2.

Further, the third pattern unit P3 may be formed to contact the light transmission unit T1. That is, one of internal surfaces of grooves formed by the third pattern unit P3 may be formed of the translucent electrode layer 250 filled in the light transmission unit T1. For example, the third pattern unit P3 may abut, e.g., be in a flush arrangement with, the light transmission unit T1. The third pattern unit P3, e.g., the insulation material in the third pattern unit P3, may be in contact with the translucent electrode layer 250 filling both the light transmission unit T1 and the second pattern unit P2.

As such, if the light transmission unit T1 is formed close to the second pattern unit P2 and/or the third pattern unit P3, as a distance between the second pattern unit P2 and the third pattern unit P3 may be decreased, a non-generation area D1 may be reduced, thereby improving a generating efficiency of the solar cell 200.

Alternatively, if the distance between the second pattern unit P2 and the third pattern unit P3 is maintained, a size of the light transmission unit T1 may be increased, thereby improving light translucency of the solar cell 200.

FIGS. 5 to 8 illustrate cross-sectional views depicting stages in a method of manufacturing the solar cell 100 of FIGS. 2 and 3 according to an exemplary embodiment. The method may also be used to manufacture the solar cell 200 of FIG. 4.

According to the method referring to FIGS. 5 through 8, first, the rear electrode layer 120 may be formed on the substrate 110, and the rear electrode layer 120 may be divided into multiple parts by performing a first patterning process as shown in FIG. 5.

The rear electrode layer 120 may be formed by coating a conductive paste on the substrate 110 and then performing a thermal process, or by performing a process, such as a plating process. Alternatively, for example, the rear electrode layer 120 may be formed via a sputtering process using a Mo target.

The first patterning process may be performed via a laser scribing process. The laser scribing process is a process that includes evaporating some of the rear electrode layer 120 by irradiating a laser beam towards the substrate 110 from a bottom of the substrate 110. Accordingly, first separation grooves of the first pattern unit P1 may be formed to divide the rear electrode layer 120 at regular intervals.

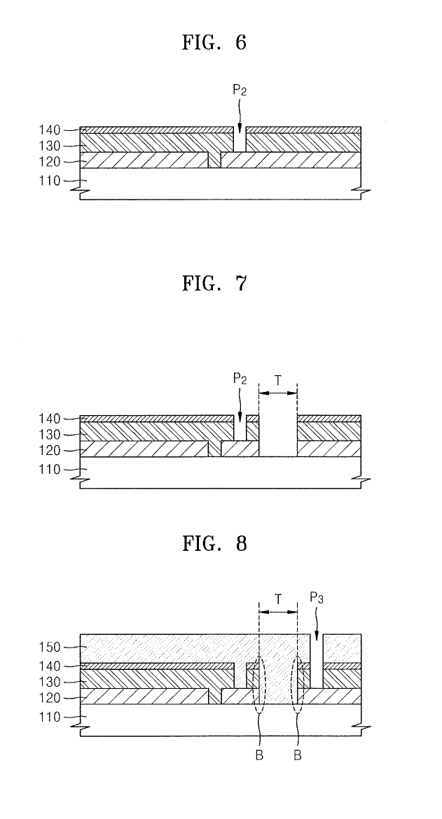

Next, as shown in FIG. 6, the light absorption layer 130 and the buffer layer 140 may be formed, e.g., may be sequentially formed. A second patterning process may be performed to form the second pattern unit P2 extending through the light absorption layer 130 and the buffer layer 140.

The light absorption layer 130 may be formed by using a co-evaporation method wherein Cu, In, Ga, and Se are put into a small electric furnace installed in a vacuum chamber, and are heated to perform vacuum deposition. According to another exemplary embodiment, the light absorption layer 130 may be formed by using a sputtering/selenization method wherein a CIG-based metal precursor film is formed on the rear electrode layer 120 by using a Cu target, a In target, and a Ga target, and then the CIG-based metal precursor film is thermally treated in a hydrogen selenide (H₂Se) gas atmosphere so that the CIG-based metal precursor film reacts with Se to form a CIGS-based light absorption layer. According to yet another exemplary embodiment, the light absorption layer 130 may be formed by using an electro-deposition method or a molecular organic chemical vapor deposition (MOCVD) method.

The buffer layer 140 reduces a band gap difference between the light absorption layer 130 of a P-type and the translucent electrode layer 150 of an N-type, and may reduce re-combination of electrons and holes that may be generated on an interface between the light absorption layer 130 and the translucent electrode layer 150. The buffer layer 140 may be formed via a chemical bath deposition (CBD) method, an atomic layer deposition (ALD) method, or an ion lay gas reaction (ILGAR) method.

As such, after forming the light absorption layer 130 and the buffer layer 140, the second patterning process is performed. The second patterning process may be performed via mechanical scribing wherein the second pattern unit P2 is formed by moving a sharp object, such as a needle, in a direction parallel to the first pattern unit P1 at a location spaced apart from the first pattern unit P1. Alternatively, the second patterning process may be performed by using a laser beam.

The second patterning process divides the light absorption layer 130 and corresponding portions of the buffer layer 140 into multiple parts. The second pattern unit P2 formed via the second patterning process extends to a top surface of the rear electrode layer 120 to expose the rear electrode layer 120.

As shown in FIG. 7, the rear electrode layer 120, the light absorption layer 130, and the buffer layer 140 that exist in an area where the light transmission unit T is to be formed are removed together to expose a top surface of the substrate 110. The light transmission unit T and the second pattern unit P2 may be formed in a same stage or in different stages. Accordingly, the first pattern unit P1 and the second pattern unit P2 may be formed together with the light transmission unit T on the substrate 110.

The rear electrode layer 120, the light absorption layer 130, and the buffer layer 140 may be removed by using a laser scribing method that uses a laser having a wavelength from about 1060 to about 1064 nm, a pulse width from about 10 to about 100 ns, and power from about 0.5 to about 20 W, but embodiments are not limited thereto.

The light transmission unit T formed by removing the rear electrode layer 120, the light absorption layer 130, and the buffer layer 140 may be formed spaced apart from the second pattern unit P2, e.g., as illustrated in FIG. 3. According to another exemplary embodiment, as described with reference to FIG. 4, the light transmission unit T may be formed to overlap with the entire or a part of the second pattern unit P2. The light transmission unit T formed may have a width from about 0.1 to about 4 mm. However, embodiments are not limited thereto, e.g., the width of the light transmission unit T may be adjusted to be appropriate for a BIPV system in which the solar cell 100, 200 is to be used.

As shown in FIG. 8, after forming the translucent electrode layer 150, a third patterning process may be performed.

The translucent electrode layer 150 may be formed of a transparent conductive material, such as ZnO:B, ITO, and/or IZO. The translucent electrode layer 150 may be formed by using a metal organic chemical vapor deposition (MOCVD) method, a low pressure chemical vapor deposition (LPCVD) method, or a sputtering method.

The translucent electrode layer 150 is also formed in the second pattern unit P2 and the light transmission unit T, thereby electrically connecting the light absorption layers 130 divided by the second pattern unit P2. Also, the translucent electrode layer 150 may be filled in the light transmission unit T, thereby reducing the possibility of and/or preventing a shunt that may occur during the removal of the translucent electrode layer 150 to form the light transmission unit T.

The third patterning process may be performed via a mechanical scribing method. The third pattern unit P3 formed via the third patterning process may extend to a top surface of the rear electrode layer 120, e.g., to expose the top surface of the rear electrode layer 120, to form a plurality of photoelectric conversion cells. An insulation layer may be formed by disposing air in the third pattern unit P3, and the plurality of first to nth photoelectric conversion cells Cl to Cn may be connected to one another in series.

The third pattern unit P3 may be formed in such a way that the light transmission unit T is located between the second pattern unit P2 and the third pattern unit P3. Thus, the light transmission unit T is located in a non-generation area of the solar cell 100. Accordingly, even if a shunt occurs in a portion “B”, deterioration of efficiency of the solar cell 100 may be prevented.

The third pattern unit P3 may be formed to contact the light transmission unit T, according to an exemplary embodiment. That is, one of internal surfaces of grooves formed by the third pattern unit P3 may be formed along the translucent electrode layer 250 filled in the light transmission unit T. In other words, the light transmission unit T may contact the second pattern unit P2 and/or the third pattern unit P3. In this case, since a size of the non-generation area inside the solar cell 100 is reduced, generation efficiency of the solar cell 100 may be improved. Alternatively, since a size of the light transmission unit T is increased, light translucency of the solar cell 100 may be improved.

Although not shown FIG. 8, a top surface of the translucent electrode layer 150 may be textured. Here, texturing denotes forming a ribbed pattern on a surface via a physical or chemical method. As such, when the top surface of the translucent electrode layer 150 is roughened via texturing, reflectivity of incident light may be reduced, and thus the amount of light captured may be increased. Accordingly, optical loss may be reduced.

The solar cells according to one or more embodiments are not limited to the structures and methods described above, and the entire or some of the embodiments may be selectively combined for various modifications.

According to the one or more of the above embodiments, a light transmission unit is formed between a second pattern unit and a third pattern unit, thereby reducing the possibility of and/or preventing deterioration of generation efficiency due to a shunt. Also, the light transmission unit may be formed to contact the second pattern unit and/or the third pattern unit, thereby minimizing a non-generation area.

By way of summation and review, measures for high performance building are being prepared, e.g., by Green Growth Korea, and include one of a number of energy reduction measures. Further, as generating efficiencies of solar cells have improved, solar cells are in the spotlight as next generation energy sources such as batteries. A building integrated photovoltaic (BIPV) system using solar cells as envelop finishing materials or windows and doors of buildings is receiving attention. In the BIPV system, translucency and photoelectric conversion efficiency of solar cells may be important since the solar cells may satisfy performance criteria as envelop finishing materials and achieve power supply via self-power generation.

Embodiments relate to a solar cell capable of preventing deterioration of generation efficiency due to a shunt, and a method of manufacturing the solar cell. Embodiments also relate to a solar cell having improved efficiency by minimizing a non-generation area. Further, additional aspects set forth in part in the description above and, in part, will be apparent from the description, or may be learned by practice of the embodiments.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A solar cell, comprising:
a substrate;
a rear electrode layer on the substrate, the rear electrode layer being divided by a first pattern unit;
a light absorption layer on the rear electrode layer, the light absorption layer being divided by a second pattern unit, the second pattern unit being spaced apart from the first pattern unit;
a translucent electrode layer on the light absorption layer, the translucent electrode layer being divided by a third pattern unit, the third pattern unit being spaced apart from the first and second pattern units; and
a light transmission unit extending through the rear electrode layer and the light absorption layer, the light transmission unit being between the second pattern unit and the third pattern unit.

2. The solar cell as claimed in claim 1, wherein the translucent electrode layer fills the second pattern unit and the light transmission unit.

3. The solar cell as claimed in claim 1, wherein the third pattern unit exposes a top surface of the rear electrode layer and the third pattern unit includes therein an insulating unit that is on the rear electrode layer.

4. The solar cell as claimed in claim 1, wherein the light transmission unit overlaps the second pattern unit.

5. The solar cell as claimed in claim 1, further comprising a buffer layer between the light absorption layer and the translucent electrode layer.

6. The solar cell as claimed in claim 1, wherein the rear electrode layer includes Mo.

7. The solar cell as claimed in claim 1, wherein the light absorption layer includes Cu, In, Ge, and Se.

8. The solar cell as claimed in claim 1, wherein the third pattern unit contacts the light transmission unit.

9. The solar cell as claimed in claim 1, wherein the light transmission unit is directly between the second pattern unit and the third pattern unit such that the light transmission unit contacts the third pattern unit and the second pattern unit.

10. The solar cell as claimed in claim 1, wherein:
the first pattern unit and the light transmission unit expose different regions of a top surface of the substrate, the first pattern unit being spaced apart from the light transmission unit by the second pattern unit,
the second pattern unit and the third pattern unit expose different regions of a top surface of the rear electrode layer, the third pattern unit being spaced apart from the first pattern unit by the light transmission unit and the second pattern unit,
the light absorption layer fills the first pattern unit and the translucent electrode layer fills the second pattern unit and the light transmission unit, and
an insulating material fills the third pattern unit.

11. The solar cell as claimed in claim 10, wherein the light transmission unit abuts the second pattern unit and the third pattern unit, the insulating material in the third pattern unit being in contact with a portion of the translucent electrode layer that fills both the second pattern unit and the light transmission unit.

12. A method of manufacturing a solar cell, the method comprising:
forming a rear electrode layer on a substrate and performing a first patterning process to form a first pattern unit that divides the rear electrode layer;
forming a light absorption layer on the rear electrode layer and performing a second patterning process to form a second pattern unit that divides the light absorption layer, the second pattern unit being formed at a location spaced apart from the first pattern unit;
exposing a portion of a top surface of the substrate by removing parts of the light absorption layer and the rear electrode layer to form a light transmission unit;
forming a translucent electrode layer on the light absorption layer and on the portion of the top surface of the substrate that is exposed by the light transmission unit; and
performing a third patterning process to form a third pattern unit at a location spaced apart from the first and second pattern units.

13. The method as claimed in claim 12, wherein the parts of the light absorption layer and the rear electrode layer that are removed to expose the portion of the top surface of the substrate are between the second pattern unit and the third pattern unit.

14. The method as claimed in claim 12, wherein the parts of the light absorption layer and the rear electrode layer are removed by radiating a laser.

15. The method as claimed in claim 12, further comprising forming a buffer layer on the light absorption layer before forming the second pattern unit.

16. The method as claimed in claim 12, wherein the third patterning process is performed via a mechanical scribing method.

17. The method as claimed in claim 12, wherein the parts of the light absorption layer and the rear electrode layer that are removed to form the light transmission unit abut the second pattern unit.

18. The method as claimed in claim 12, wherein the third pattern unit is formed to contact an area where the light absorption layer and the rear electrode layer are removed.

19. The method as claimed in claim 12, wherein:
forming the first pattern unit and the light transmission unit includes exposing different regions of the top surface of the substrate such that the first pattern unit is spaced apart from the light transmission unit by the second pattern unit,
forming the second pattern unit and the third pattern unit includes exposing different regions of a top surface of the rear electrode layer such that the third pattern unit is spaced apart from the first pattern unit by the light transmission unit and the second pattern unit,
forming the light absorption layer includes filling the first pattern unit,
forming the translucent electrode layer includes filling the second pattern unit and the light transmission unit, and
the third pattern unit is filled with an insulating material.

20. The method as claimed in claim 19, wherein the light transmission unit is formed to abut the second pattern unit and the third pattern unit such that the insulating material in the third pattern unit is in contact with a portion of the translucent electrode layer that fills both the second pattern unit and the light transmission unit.
